(19) United States
(12) Patent Application Publication
(10) Pub. No.: US 2005/0250054 A1
(43) Pub. Date: Nov. 10, 2005

(54) Development of photolithographic masks for semiconductors

(76) Inventor: Ching-Yu Chang, Yilang County (TW)

Correspondence Address: SLATER & MATSIL, L.L.P., 17950 PRESTON ROAD, SUITE 1000, DALLAS, TX, 75252, US

(21) Appl. No.: 10/937,177

(22) Filed: Sep. 9, 2004

Related U.S. Application Data
(60) Provisional application No. 60/569,690, filed on May 10, 2004.

(51) Int. Cl. G03F 7/30

(52) U.S. Cl. 430/329; 430/331

(57) ABSTRACT

A method of forming a photolithographic mask for use in fabricating a semiconductor device is provided. The method includes forming a layer of photoresist material on a wafer and exposing the photoresist material to a light source. The photoresist material is developed, and before the wafer dries, the wafer is cleaned with one or more cleaning liquids. The cleaning liquid may be a surfactant, an acid, a dissolved gas solution (e.g., CO₂, SO₂, SO₃, NH₃, NO₂, or the like), deionized water, or the like. Thereafter, the wafer is dried. The wafer may be dried, for example, by a spin dry process, a gas purge process using, for example, compressed dry air, N₂, CO₂, Ar, or the like, or a drying alcohol such as IPA vapor.

This application claims the benefit of U.S. Provisional Application No. 60/569,690 filed on May 10, 2004, entitled Development of Photolithographic Masks for Semiconductors, which application is hereby incorporated herein by reference.

### TECHNICAL FIELD

The present invention relates generally to semiconductors, and more particularly, to a method of forming a photolithographic mask for use in fabricating a semiconductor device.

### BACKGROUND

Fabrication of semiconductor devices typically involves the use of photolithographic techniques. Photolithographic techniques involves applying a layer of photoresist material, irradiating (exposing) portions of the photoresist material in accordance with a desired pattern, developing the photoresist material to remove portions of the photoresist material to expose portions of the underlying material, and rinsing away the excess photoresist material, thereby creating a photolithographic mask. An etching process may then be performed in which the photolithographic mask protects portions of the underlying material, thereby etching the underlying material in accordance with the desired pattern.

The photoresist material may be a negative photoresist or a positive photoresist. A negative photoresist material is less soluble in the exposed regions. Thus, the developing step described above removes the unexposed portions of the negative photoresist material. On the other hand, a positive photoresist material is more soluble in the exposed region. In this case, the developing step described above removes the exposed portions of the positive photoresist material.

The photolithographic mask formed by photolithographic process, however, may be defective, particularly in smaller designs in which the mask has a higher aspect ratio. As designs decrease, the ratio of the height of the mask to the width of the standing line (i.e., the aspect ratio) increases. Because a certain width is required for the mask to protect the underlying material during a subsequent etching process, the aspect ratio can not be decreased easily.

One problem caused by the high aspect ratio is pattern collapse. Generally, pattern collapse is due to the capillary force induced by the hydrophilic nature of the developing and rinsing solution. One attempt at solving this problem is described in U.S. Pat. No. 6,451,510, which described a process in which a surfactant was applied after or with a deionized water (DI) rinse. The surfactant attempted to reduce the surface tension of the liquid, thereby decreasing the capillary force.

Another problem caused by the high hydrophobic nature of the unexposed resist and BARC surface is surface defects. Surface defects may be formed during the spin dry process. One attempt at solving this problem is described in U.S. Pat. No. 6,613,499, which describes a process in which a surfactant was applied after or with a deionized water rinse. The addition of the surfactant attempts to change the hydrophobic surface to a more hydrophilic surface, therefore decrease the defect density.

It has been found, however, that allowing the wafer to dry prior to the final drying step may cause additional pattern collapses, thereby decreasing the yield and the process window. This problem is particularly troublesome with processes that use photoresist material irradiated by shorter wavelength sources. For example, photoresist material irradiated with 193 nm is not as hard as photoresist material irradiated with longer wavelengths, such as 248 nm. Furthermore, the capillary force, which induce the pattern collapse, increase as the pattern size decrease.

Accordingly, there is a need for an improved method of forming a photolithographic mask.

### SUMMARY OF THE INVENTION

These and other problems are generally solved or circumvented, and technical advantages are generally achieved, by preferred embodiments of the present invention which provides a method of forming a photolithographic mask for use in fabricating a semiconductor device.

In accordance with an embodiment of the present invention, a method for processing a photoresist layer formed on a wafer is provided. The method includes exposing the photoresist layer, developing the photoresist layer with a developing liquid, cleaning the wafer with a first cleaning liquid, and cleaning the wafer with a second cleaning liquid prior to the first cleaning liquid drying.

In accordance with another embodiment of the present invention, a method of processing a photoresist layer formed on a wafer is provided. The method includes exposing the photoresist layer, developing the photoresist layer with a developing liquid, cleaning the wafer with a deionized water (DI) rinse, and cleaning the wafer with a cleaning liquid prior to the DI rinse drying.

In accordance with an embodiment of the present invention, a method for processing a photoresist layer formed on a wafer is provided. The method includes exposing the photoresist layer, developing the photoresist layer with a developing liquid, cleaning the wafer with a cleaning liquid prior to the developing liquid drying, and drying the wafer, wherein drying the wafer includes a gas purge.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a process flow diagram for a method of forming a photolithographic mask in accordance with an embodiment of the present invention;

FIG. 2 is a process flow diagram for a method of forming a photolithographic mask in accordance with an embodiment of the present invention; and

FIG. 3 is a process flow diagram for a method of forming a photolithographic mask in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

It should be noted that the processes described herein assume that a layer of photoresist material has been formed, patterned, and exposed on a wafer. Accordingly, the processes described herein begin with a developing step. It should be further noted that the processes described herein are particularly useful in situations in which the photoresist material is irradiated with a light source emitting wavelengths less than or equal to about 193 nm, and especially useful with immersion lithography techniques utilizing a light source emitting wavelengths less than or equal to about 248 nm.

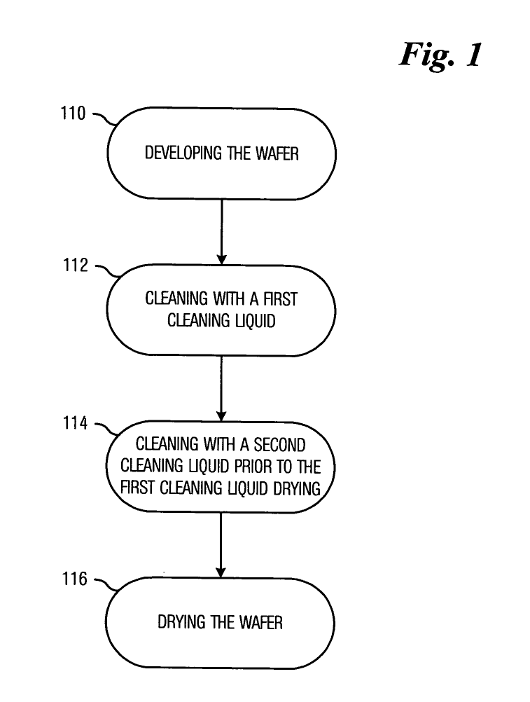

FIG. 1 is a process flow diagram for a method of forming a photolithographic mask in accordance with an embodiment of the present invention. The process begins in step 110, wherein a developing process is performed. Generally, the developing step includes applying a developer in accordance with any known process. Common processes known in the art for applying a developer include quiescence, immersion, spray, or puddle. In an embodiment, the developer is an alkali solvent with a PH value greater than 9, such as a solution of tetramethylammonium (TMAH), having a TMAH concentration of about 0.1% to about 2.38%.

Next, in step 112, a first cleaning solution is applied prior to the developing solution drying. As mentioned above, it has been found that allowing the wafer to dry prior to the drying step discussed below may cause the photoresist pattern to collapse. Accordingly, care should be taken to ensure that the first cleaning solution (and any other subsequent cleaning steps) be performed prior to the wafer drying. The first cleaning solution may be water or DI water, a solution containing salt, an ionic surfactant, a non-ionic surfactant, or a dissolved gas solution. It is preferred that the first cleaning solutions, particularly DI, have a pH value greater than or less than about 7. It has been found that a DI has a high hydrogen bonding water molecular structure, causing high capillary force and inducing pattern bending.

It should be noted that additives may be added to the first cleaning solution, such as DI. In an embodiment, an additive may be added to reduce the DI surface tension and the capillary force. In another embodiment, an additive may be added to the DI such that the additive reacts with the photoresist and reduce hydrogen bonding between the DI and the photoresist. In this manner, the capillary force between the DI and the photoresist may be reduced.

Solutions that may be used include a solution of 1-ethyl-3 (3-dimethylaminopropyl) carbodiimide hydrochloride (EDAC) and diethylamine. This solution changes the resist surface polymer from carboxylic group (hydrophilic) to ether. The ester group is hydrophobic, and therefore, the capillary force may be reduced. Surfactants that may be used include a solution comprised of at least one of OH, Si, PO₄, SO₄ functional group polymer. For example, IPA, glycerol, PFOS, Rx(CH₂CHOH)yRz, Rx(CHOHCHOH)yRz, R₂PO₄H, R₂SO₄H (where the R means alkyl group contained at least one C). In an embodiment in which a dissolved gas solution is used, CO₂, SO₂, SO₃, NH₃, NO₂, and the like have been found to be particularly useful.

In step 114, a second cleaning process is performed. Again, care should be taken to ensure that the wafer does not dry between the first cleaning process (step 112) and the second cleaning process (step 114). The second cleaning solution may be water, DI water, a solution containing salt, an ionic surfactant, a non-ionic surfactant, an acid, or a dissolved gas solution. In an embodiment in which a dissolved gas solution is used, CO₂, SO₂, SO₃, NH₃, NO₂, and the like have been found to be particularly useful. Acids that have been found that may be used in accordance with the present invention include H₂SO₄, HCl, a solution of CO₂ and water, or the like. A chemical solution that may be used includes a solution of 1-ethyl-3 (3-dimethylaminopropyl) carbodiimide hydrochloride (EDAC) and diethylamine. This solution changes the resist surface polymer from carboxylic group (hydrophilic) to ether. The ester group is hydrophobic, and therefore, the capillary force may be reduced. Surfactants that may be used include a solution comprised at least one of OH, Si, PO₄, SO₄ functional group polymer. For example, IPA, glycerol, PFOS, Rx(CH₂CHOH)yRz, Rx(CHOHCHOH)yRz, R₂PO₄H, R₂SO₄H (where the R means alkyl group contained at least one C).

Thereafter, in step 116, a drying process may be performed. In an embodiment, the drying process is performed with a single-wafer spin-dry tool utilizing a gas purge. Spin drying is a common practice in the industry due to its ability to remove surface moisture from the surface of the wafer. The gas purge may be performed using compressed dry air (CDA), N₂, CO₂, Ar, or the like during a spin-drying process to help reduce the amount of pattern collapse. The gas may be introduced during the spin drying process with a 30 to 300 mm/sec swing speed from the wafer center to the wafer edge or across the wafer. A spin dry speed from an initial speed of about 5 rpm with at least 1 second and increasing the spin speed with multi-step to a higher speed (preferably not higher than 5000 rpm) is preferred for drying. The gas content may use at least one of above examples with purge speed greater than about 1 sccm. In other embodiments, the drying process may utilize a drying alcohol (e.g., isopropyl alcohol (IPA)). Other drying methods may be used.

It should also be noted that it has been found that removing the wafer from the second cleaning liquid at a slow speed, such as speed less than 200 mm/sec, has been found to further reduce the pattern collapse.

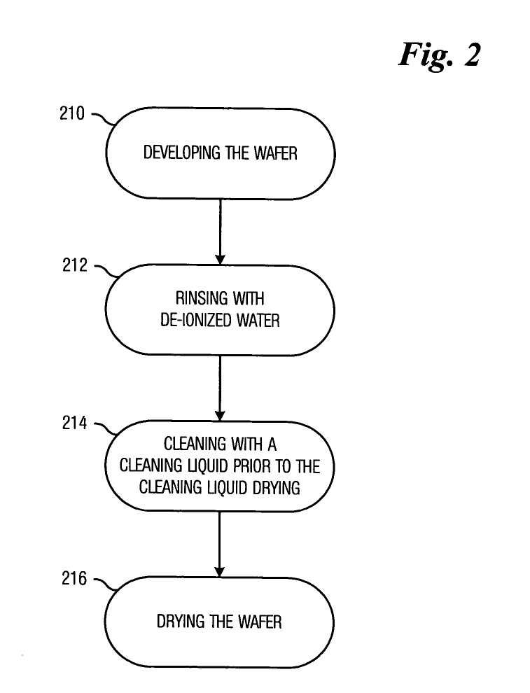

FIG. 2 is a process flow diagram for a method of forming a photolithographic mask in accordance with an embodiment of the present invention. The process begins in step 210, wherein a developing process is performed, which may be performed substantially similar to the process described above with reference to step 110 of FIG. 1.

Next, a DI rinse and a first cleaning process is performed in steps 212 and 214, respectively. The first cleaning process is performed after the water or DI water rinse and prior to the wafer drying. As discussed above, allowing the wafer to dry prior to the cleaning and rinsing processes being completed may cause pattern collapse. Accordingly, care should be taken to ensure that the wafer does not dry between the water rinse and the first cleaning process.

The first cleaning process may include cleaning the wafer with a solution containing salt, an ionic surfactant, a non-ionic surfactant, an acid, or a dissolved gas solution. In an embodiment in which a dissolved gas solution is used, CO₂, SO₂, SO₃, NH₃, NO₂, and the like have been found to be particularly useful. Acids that have been found that may be used in accordance with the present invention include H₂SO₄, HCl, a solution of CO₂ and water, or the like. A chemical solution that may be used includes a solution of 1-ethyl-3 (3-dimethylaminopropyl) carbodiimide hydrochloride (EDAC) and diethylamine. Surfactants that may be used include a solution comprised at least one of OH, Si, PO₄, SO₄ functional group polymer. For example, IPA, glycerol, PFOS, Rx(CH₂CHOH)yRz, Rx(CHOHCHOH)yRz, R₂PO₄H, R₂SO₄H(where the R means alkyl group contained at least one C)

Thereafter, in step 216, a drying process may be performed. In an embodiment, the drying process may utilize a spin-dry process with a gas purge as described above. In other embodiment, the drying process may utilize a drying alcohol (e.g., IPA). Other drying processes may be utilized.

It should also be noted that it has been found that removing the wafer from the first cleaning liquid bath at a slow speed, such as speed less than 200 mm/sec, has been found to further reduce pattern collapse.

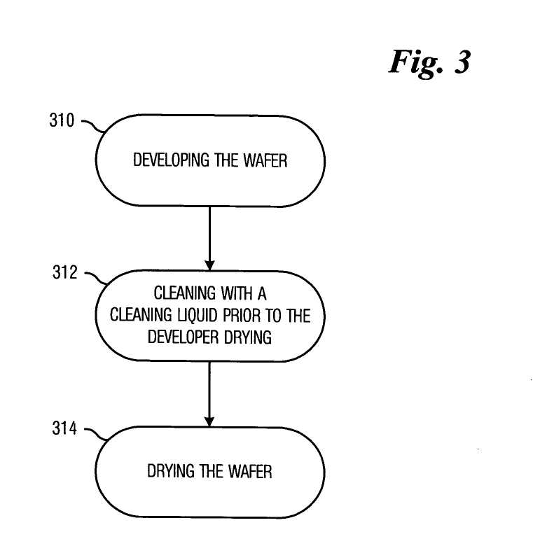

FIG. 3 is a process flow diagram for a method of forming a photolithographic mask in accordance with an embodiment of the present invention. The process begins in step 310, wherein a developing process is performed, which may be performed substantially similar to the process described above with reference to step 110 of FIG. 1.

Next, a cleaning process is performed in step 312. The cleaning process is performed after the developing process has been completed, but prior to the wafer drying. As discussed above, allowing the wafer to dry prior to the cleaning and rinsing processes being completed may cause pattern collapse. Accordingly, care should be taken to ensure that the wafer does not dry between the developing and the cleaning process.

The cleaning process may include cleaning the wafer with a solution containing salt, an ionic surfactant, a non-ionic surfactant, an acid, or a dissolved gas solution. In an embodiment in which a dissolved gas solution is used, CO₂, SO₂, SO₃, NH₃, NO₂, and the like have been found to be particularly useful. Acids that have been found that may be used in accordance with the present invention include H₂SO₄, HCl, a solution of CO₂ and water, or the like. A chemical solution that may be used includes a solution of 1-ethyl-3 (3-dimethylaminopropyl) carbodiimide hydrochloride (EDAC) and diethylamine. This solution changes the resist surface polymer from carboxylic group (hydrophilic) to ether. The ester group is hydrophobic, and therefore, the capillary force may be reduced. Surfactants that may be used include a solution comprised of at least one of OH, Si, PO₄, SO₄ functional group polymer. For example, IPA, glycerol, PFOS, Rx(CH₂CHOH)yRz, Rx(CHOHCHOH)yRz, R₂PO₄H, R₂SO₄H (where the R means alkyl group contained at least one C).

Thereafter, in step 316, a drying process, such as a spin dry process, may be performed. In an embodiment, the drying process may utilize a spin-dry process with a gas purge as described above. In other embodiment, the drying process may utilize a drying alcohol (e.g., IPA). Other drying processes may be utilized.

It should appreciated that embodiments of the present invention provide a method to reduce the capillary force during processing. In an embodiment, the first cleaning liquid may be water solution, or DI, that removes the water-soluble polymer. The second cleaning liquid may be any material that can bond with the photoresist sidewall surface, changing the photoresist surface from hydrophilic to less hydrophilic. The bonding force between the cleaning liquid and the photoresist may be, for example, chemical bonding, ionic bonding, van der Waal bonding, or the like.

For example, chemical bonding may occur when using a solution of 1-ethyl-3 (3-dimethylaminopropyl) carbodiimide hydrochloride (EDAC) and diethylamine. Ionic bonding may occur using CO₂ or acid water to bond the carboxylic group with the H+ molecule. These types of bonding reduce the resist surface OH group and carboxylic group by adding another organic molecule and H molecule to form more hydrophobic surface, thereby reducing the capillary force.

It should also be noted that it has been found that removing the wafer from the first cleaning liquid bath at a slow speed, such as speed less than 200 mm/sec, has been found to further reduce pattern collapse.

Although the present invention and its advantages have been described in detail, it should be understood that various changes, substitutions and alterations can be made herein without departing from the spirit and scope of the invention as defined by the appended claims. For example, the types of materials and processes may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A method for processing a photoresist layer formed on a wafer, the method comprising:
exposing the photoresist layer;
developing the photoresist layer with a developing liquid;
cleaning the wafer with a first cleaning liquid; and
cleaning the wafer with a second cleaning liquid prior to the first cleaning liquid drying.

2. The method of claim 1, wherein the exposing comprises exposing the photoresist layer to a light source having a wavelength of less than or equal to about 193 nm.

3. The method of claim 1, wherein the developing liquid comprises TMAH.

4. The method of claim 3, wherein the developing liquid has a concentration of TMAH of about 0.1% to about 2.8%.

5. The method of claim 1, wherein the first cleaning liquid comprises deionized water, a salt solution, an ionic surfactant, a non-ionic surfactant, an acid, or a dissolved gas solution.

6. The method of claim 5, wherein the dissolved gas solution comprises CO₂, SO₂, SO₃, NH₃, or NO₂.

7. The method of claim 1, wherein the second cleaning liquid comprises deionized water, a salt solution, an ionic surfactant, a non-ionic surfactant, an acid, or a dissolved gas solution.

8. The method of claim 7, wherein the dissolved gas solution comprises CO₂, SO₂, SO₃, NH₃, or NO₂.

9. The method of claim 7, wherein the acid comprises H₂SO₄, HCl, or a solution of CO₂ and water.

10. The method of claim 1, further comprising drying the wafer, wherein the drying is performed by a gas purge with compressed dry air, N₂, CO₂, or Ar, a spin dry, an isopropyl alcohol vapor process, or a combination thereof.

11. The method of claim 1, wherein the wafer is removed from the second cleaning liquid at a speed of less than about 200 mm/sec.

12. The method of claim 1, wherein the first cleaning liquid comprises a solution of 1-ethyl-3 (3-dimethylaminopropyl) carbodiimide hydrochloride (EDAC) and diethylamine.

13. The method of claim 1, wherein the second cleaning liquid comprises a solution of 1-ethyl-3 (3-dimethylaminopropyl) carbodiimide hydrochloride (EDAC) and diethylamine.

14. A method for processing a photoresist layer formed Qn a wafer in an immersion lithography, the method comprising:
exposing the photoresist layer in an immersion bath exposure system;
developing the photoresist layer with a developing liquid;
cleaning the wafer with a first cleaning liquid; and
cleaning the wafer with a second cleaning liquid prior to the first cleaning liquid drying.

15. The method of claim 14, wherein the exposing comprises exposing the photoresist layer to a light source having a wavelength of less than or equal to about 193 nm.

16. The method of claim 14, wherein the developing liquid comprises TMAH.

17. The method of claim 16, wherein the developing liquid has a concentration of TMAH of about 0.1% to about 2.8%.

18. The method of claim 14, wherein the first cleaning liquid comprises deionized water, a salt solution, an ionic surfactant, a non-ionic surfactant, an acid, or a dissolved gas solution.

19. The method of claim 18, wherein the dissolved gas solution comprises CO₂, SO₂, SO₃, NH₃, or NO₂.

20. The method of claim 14, wherein the second cleaning liquid comprises deionized water, a salt solution, an ionic surfactant, a non-ionic surfactant, an acid, or a dissolved gas solution.

21. The method of claim 20, wherein the dissolved gas solution comprises CO₂, SO₂, SO₃, NH₃, or NO₂.

22. The method of claim 20, wherein the acid comprises H₂SO₄, HCl, or a solution of CO₂ and water.

23. The method of claim 14, further comprising drying the wafer, wherein the drying is performed by a gas purge with compressed dry air, N₂, CO₂, or Ar, a spin dry, an isopropyl alcohol vapor process, or a combination thereof.

24. The method of claim 14, wherein the wafer is removed from the second cleaning liquid at a speed of less than about 200 mm/sec.

25. The method of claim 14, wherein the first cleaning liquid comprises a solution of 1-ethyl-3(3-dimethylaminopropyl) carbodiimide hydrochloride (EDAC) and diethylamine.

26. The method of claim 14, wherein the second cleaning liquid comprises a solution of 1-ethyl-3(3-dimethylaminopropyl) carbodiimide hydrochloride (EDAC) and diethylamine.

27. A method for processing a photoresist layer formed on a wafer, the method comprising:
exposing the photoresist layer;
developing the photoresist layer with a developing liquid;
cleaning the wafer with a first cleaning liquid; and
cleaning the wafer with a second cleaning liquid prior to the first cleaning liquid drying, wherein bonding occurs between the second cleaning liquid and a surface of the photoresist layer.

28. The method of claim 27, wherein the bonding is chemical bonding.

29. The method of claim 27, wherein the bonding is ionic bonding.

30. The method of claim 27, wherein the bonding is van der Waal force bonding.

31. The method of claim 27, wherein the bonding includes Hydrogen bonding with the surface of the photoresist.

32. The method of claim 27, wherein the first cleaning liquid comprises deionized water, a salt solution, an ionic surfactant, a non-ionic surfactant, an acid, or a dissolved gas solution.

33. The method of claim 27, wherein the second material comprises a solution of 1-ethyl-3 (3-dimethylaminopropyl) carbodiimide hydrochloride (EDAC) and diethylamine.

34. A method for processing a photoresist layer formed on a wafer, the method comprising:
exposing the photoresist layer;
developing the photoresist layer with a developing liquid;
rinsing the wafer with water; and
cleaning the wafer with a cleaning liquid prior to the wafer drying.

35. The method of claim 34, wherein the water comprises deionized water.

36. The method of claim 34, wherein the exposing comprises exposing the photoresist layer to a light source having a wavelength of less than or equal to about 193 nm.

37. The method of claim 34, wherein the developing liquid comprises TMAH.

38. The method of claim 37, wherein the developing liquid has a concentration of TMAH of about 0.1% to about 2.8%.

39. The method of claim 34, wherein the cleaning liquid comprises deionized water, a salt solution, an ionic surfactant, a non-ionic surfactant, an acid, or a dissolved gas solution.

40. The method of claim 39, wherein the dissolved gas solution comprises CO₂, SO₂, SO₃, NH₃, or NO₂.

41. The method of claim 39, wherein the acid comprises H₂SO₄, HCl, or a solution of CO₂ and water.

42. The method of claim 34, further comprising drying the wafer, wherein the drying is performed by a gas purge with compressed dry air, N₂, CO₂, or Ar, a spin dry, or an isopropyl alcohol vapor process.

43. The method of claim 34, wherein the wafer is removed from the cleaning liquid at a speed of less than about 200 mm/sec.

44. The method of claim 34, wherein the cleaning liquid comprises a solution of 1-ethyl-3 (3-dimethylaminopropyl) carbodiimide hydrochloride (EDAC) and diethylamine.

45. A method for processing a photoresist layer formed on a wafer, the method comprising:
exposing the photoresist layer;
developing the photoresist layer with a developing liquid;
cleaning the wafer with a cleaning liquid prior to the developing liquid drying; and
drying the wafer, wherein drying the wafer includes a gas purge.

46. The method of claim 45, wherein the exposing comprises exposing the photoresist layer to a light source having a wavelength of less than or equal to about 193 nm.

47. The method of claim 45, wherein the developing liquid comprises TMAH.

48. The method of claim 47, wherein the developing liquid has a concentration of TMAH of about 0.1% to about 2.8%.

49. The method of claim 45, wherein the cleaning liquid comprises deionized water, a salt solution, an ionic surfactant, a non-ionic surfactant, an acid, or a dissolved gas solution.

50. The method of claim 49, wherein the dissolved gas solution comprises CO₂, SO₂, SO₃, NH₃, or NO₂.

51. The method of claim 49, wherein the acid comprises H₂SO₄, HCl, or a solution of CO₂ and water.

52. The method of claim 45, wherein the gas purge is performed with compressed dry air, N2, CO2, or Ar.

53. The method of claim 45, wherein the wafer is removed from the cleaning liquid at a speed of less than about 200 mm/sec.

54. The method of claim 45, wherein the cleaning liquid comprises a solution of 1-ethyl-3 (3-dimethylaminopropyl) carbodiimide hydrochloride (EDAC) and diethylamine.
